(19) United States
(12) Patent Application Publication
(10) Pub. No.: US 2012/0309202 A1
(43) Pub. Date: Dec. 6, 2012

(54) METHOD FOR MANUFACTURING SEMICONDUCTOR DEVICE

(76) Inventor: Toshiyuki SASAKI, Kanagawa-ken (JP)

(21) Appl. No.: 13/311,199

(22) Filed: Dec. 5, 2011

(30) Foreign Application Priority Data
May 31, 2011 (JP) 2011-122124

(51) Int. Cl. H01L 21/311

(52) U.S. Cl. 438/703; 438/694; 257/E21.308

(57) ABSTRACT

According to one embodiment, a method for manufacturing a semiconductor device, includes forming a mask film on a base material. The base material includes a first portion made of a first material and a second portion made of a second material. The mask film includes a third portion located immediately above the first portion and made of a third material and a fourth portion located immediately above the second portion and made of a fourth material. The mask film has an opening formed in both the third portion and the fourth portion.

The method includes selectively removing the first portion and the second portion respectively by etching using the mask film as a mask under a condition such that etching rate of the fourth material is higher than that of the third material and etching rate of the first material is higher than that of the second material.

### CROSS-REFERENCE TO RELATED APPLICATIONS

This application is based upon and claims the benefit of priority from the prior Japanese Patent Application No. 2011-122124, filed on May 31, 2011; the entire contents of which are incorporated herein by reference.

### FIELD

Embodiments described herein relate generally to a method for manufacturing a semiconductor device.

### BACKGROUND

Recently, in MOSFET (metal-oxide-semiconductor field-effect transistor) technology, a recessed channel transistor (RCAT) has been proposed to achieve miniaturization and increase the on-current while suppressing the source-drain leakage current. In an RCAT, the lower portion of the gate electrode is buried inside the silicon substrate.

In manufacturing an RCAT, a plurality of shallow trench isolations (STIs) are formed like stripes in the upper portion of the silicon substrate. The portion between the STIs is used as an active area (AA). Thus, a plurality of STIs and AAs are alternately arranged. By etching, a trench extending in the arranging direction of STIs and AAs is formed in the upper portion of the STIs and AAs. Subsequently, a gate insulating film is formed on the inner surface of this trench, and a gate electrode is formed inside and above this trench. Here, if the trench is not uniformly formed in the STIs and AAs, the shape of the gate electrode is made nonuniform. This degrades the characteristics of the RCAT.

### BRIEF DESCRIPTION OF THE DRAWINGS

FIGS. 1 to 14 are perspective sectional views illustrating a method for manufacturing a semiconductor device according to a first embodiment;

FIGS. 15A to 15C are process sectional views illustrating a method for manufacturing a semiconductor device according to a first comparative example;

FIGS. 16A to 16C are process sectional views illustrating a method for manufacturing a semiconductor device according to a second comparative example;

FIGS. 17A to 17C are process sectional views illustrating a method for manufacturing a semiconductor device according to a third comparative example;

FIG. 18 is a perspective sectional view illustrating a method for manufacturing a semiconductor device according to a second embodiment; and

FIG. 19 is a sectional view illustrating the method for manufacturing a semiconductor device according to the second embodiment.

### DETAILED DESCRIPTION

In general, according to one embodiment, a method for manufacturing a semiconductor device, includes forming a mask film on a base material. The base material includes a first portion made of a first material and a second portion made of a second material different from the first material. The mask film includes a third portion located immediately above the first portion and made of a third material and a fourth portion located immediately above the second portion and made of a fourth material different from the third material. The mask film has an opening formed in both the third portion and the fourth portion. The method includes selectively removing the first portion and the second portion respectively by etching using the mask film as a mask under a condition such that etching rate of the fourth material is higher than etching rate of the third material and etching rate of the first material is higher than etching rate of the second material.

Embodiments of the invention will now be described with reference to the drawings.

First, a first embodiment is described.

The embodiment relates to a method for manufacturing a semiconductor device including recessed channel transistors, such as a method for manufacturing an MRAM (magnetoresistive random access memory).

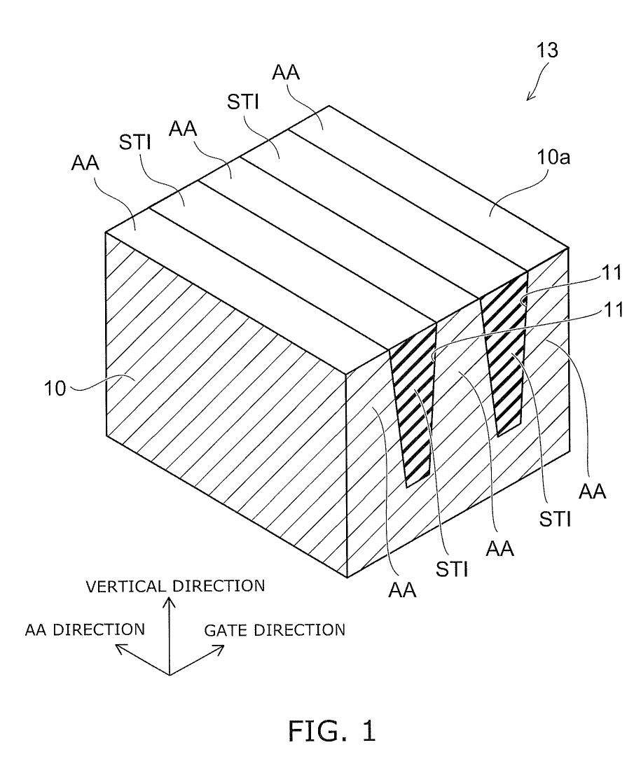

FIGS. 1 to 14 are perspective sectional views illustrating the method for manufacturing a semiconductor device according to the embodiment.

First, as shown in FIG. 1, a semiconductor substrate such as a silicon substrate 10 made of single crystal silicon is prepared. In the following, among the directions parallel to the upper surface 10a of the silicon substrate 10, two orthogonal directions are referred to as “AA direction” and “gate direction”. The direction perpendicular to the upper surface of the silicon substrate 10 is referred to as “vertical direction”.

In the upper surface 10a of the silicon substrate 10, a plurality of trenches 11 extending linearly in the AA direction are formed. The trenches 11 are periodically arranged along the gate direction. The trench 11 has an inverse taper shape with the width of the lower surface narrower than the width of the upper surface. Next, silicon oxide is buried in the trenches 11 to form shallow trench isolations STI. The upper portion of the silicon substrate 10 partitioned by the shallow trench isolations STI constitutes an active area AA made of single crystal silicon. The active area AA and the shallow trench isolation STI are shaped like stripes extending in the AA direction. The active areas AA and the shallow trench isolations STI are arranged along the gate direction. In the following, the silicon substrate 10 with the active areas AA and the shallow trench isolations STI formed therein is referred to as base material 13.

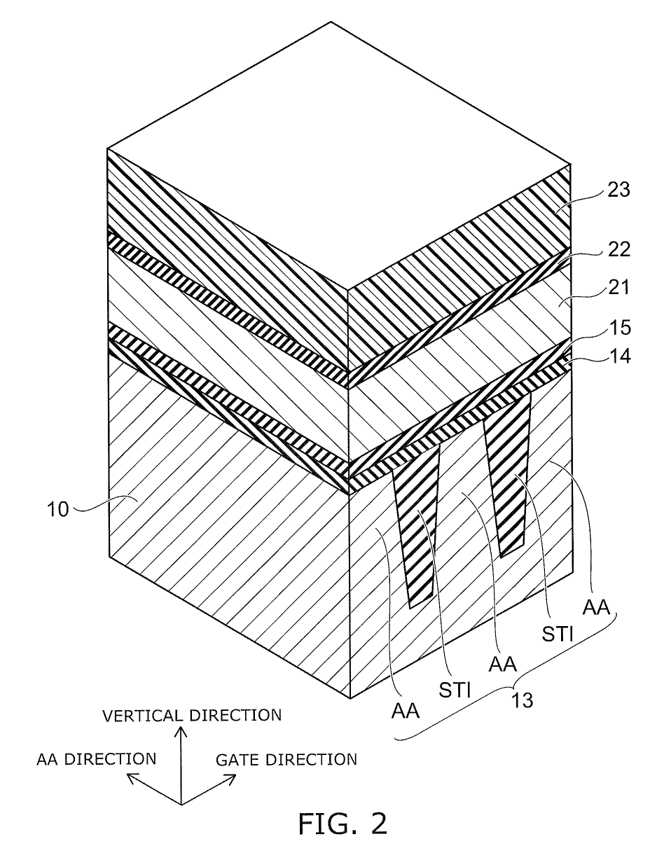

Next, as shown in FIG. 2, a sacrificial film 14 made of silicon oxide is formed on the entire surface of the base material 13. A stopper film 15 made of silicon nitride is formed on the sacrificial film 14. Next, an amorphous silicon film 21, an antireflection film 22, and a photoresist film 23 are formed in this order on the entire surface of the stopper film 15.

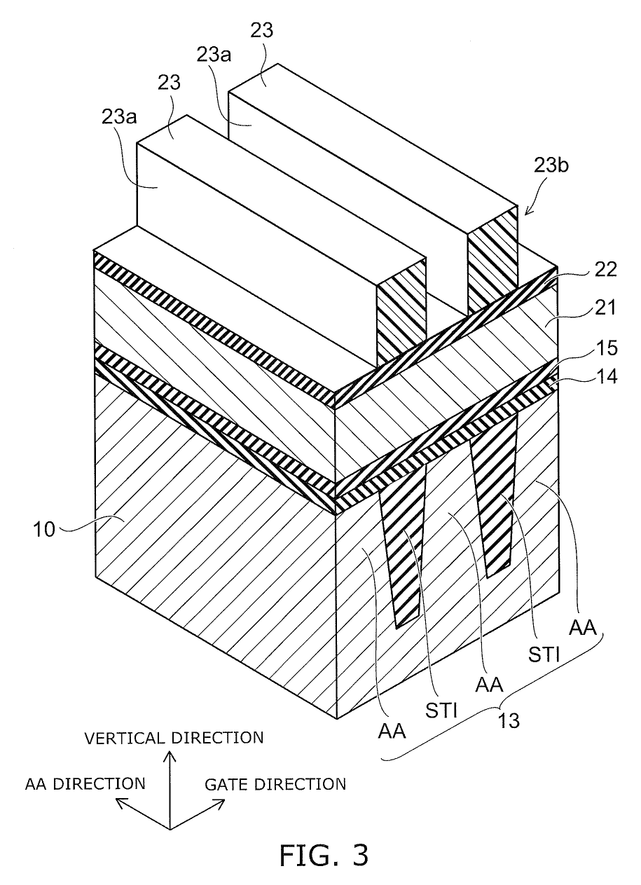

Next, as shown in FIG. 3, the photoresist film 23 is processed by lithography. Thus, an opening 23a is formed immediately above the active area AA. The opening 23a is shaped like a groove extending in the AA direction. Thus, the photoresist film 23 is patterned into a mask pattern 23b. Next, etching is performed using the mask pattern 23b as a mask and the stopper film 15 as an etching stopper. Thus, the antireflection film 22 and the amorphous silicon film 21 are selectively removed. Subsequently, ashing is performed to remove the mask pattern 23b and the antireflection film 22.

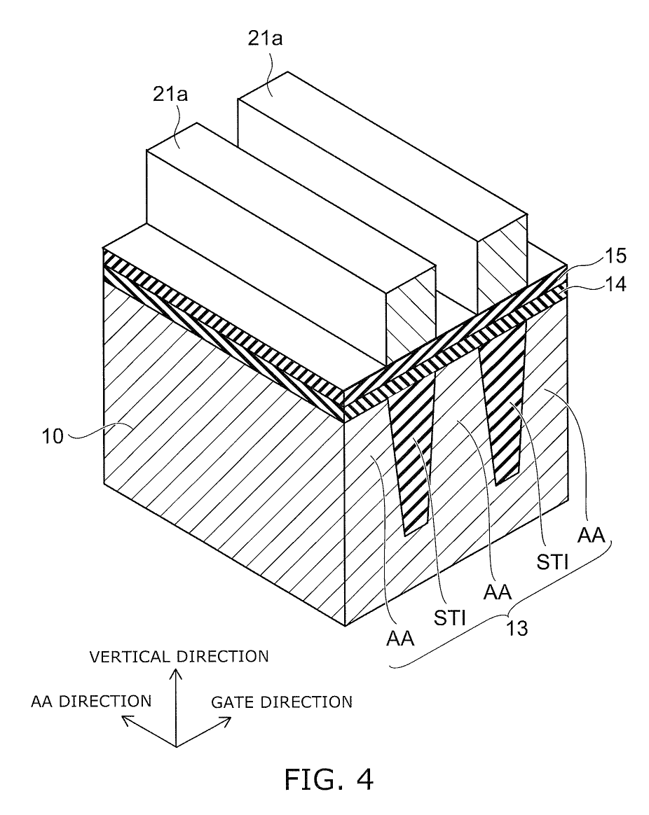

As a result, as shown in FIG. 4, the amorphous silicon film 21 (see FIG. 3) is processed into stripes extending in the AA direction. Thus, a silicon portion 21a made of amorphous silicon is formed. The silicon portion 21a is located immediately above the shallow trench isolation STI.

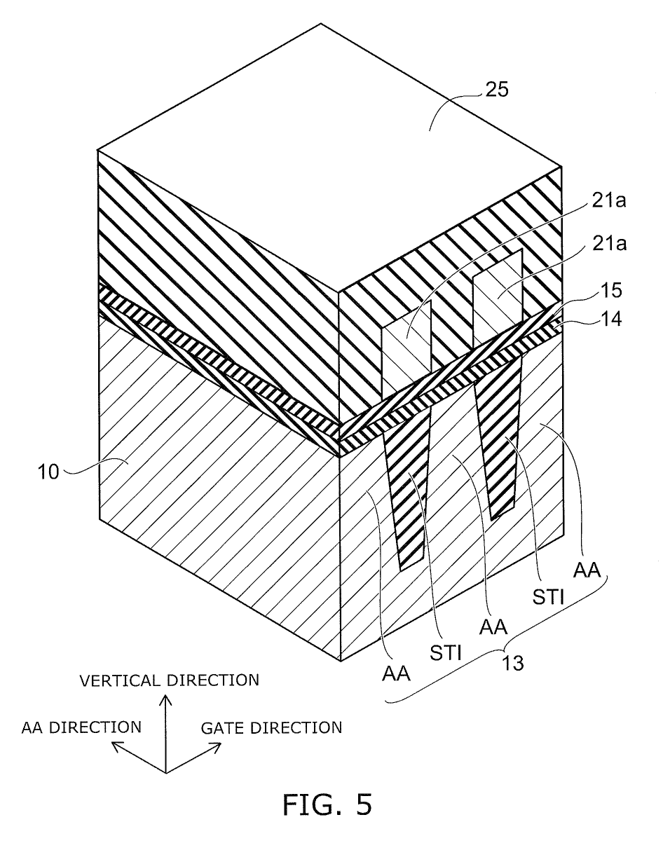

Next, as shown in FIG. 5, by the CVD (chemical vapor deposition) method using TEOS (tetraethoxysilane, Si(OC₂H₅)₄) as a raw material, silicon oxide is deposited on the entire surface to form a silicon oxide film 25 so as to cover the silicon portion 21a. The silicon oxide film 25 is buried between the silicon portions 21a and formed also above the silicon portions 21a. Next, planarization treatment such as CMP (chemical mechanical polishing) is performed on the upper surface of the silicon oxide film 25 to remove the upper portion of the silicon oxide film 25.

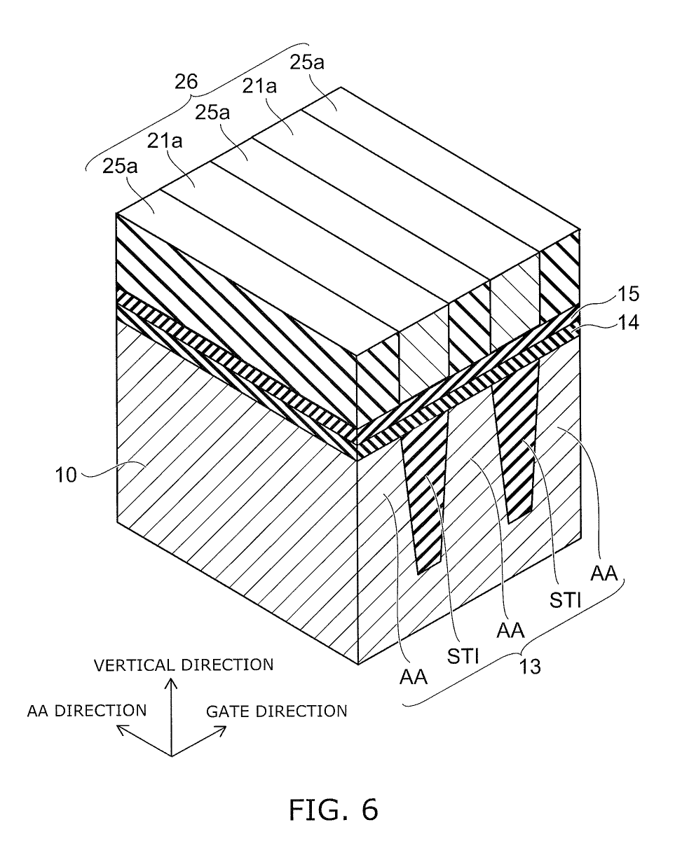

Thus, as shown in FIG. 6, the silicon oxide film 25 is removed from immediately above the silicon portion 21a. The silicon oxide film 25 is left on the lateral side of the silicon portion 21a, i.e., between the silicon portions 21a. Thus, an oxide portion 25a made of silicon oxide is formed. The oxide portion 25a is located immediately above the active area AA. Thus, a composite film 26 with the silicon portions 21a and the oxide portions 25a alternately arranged therein is formed.

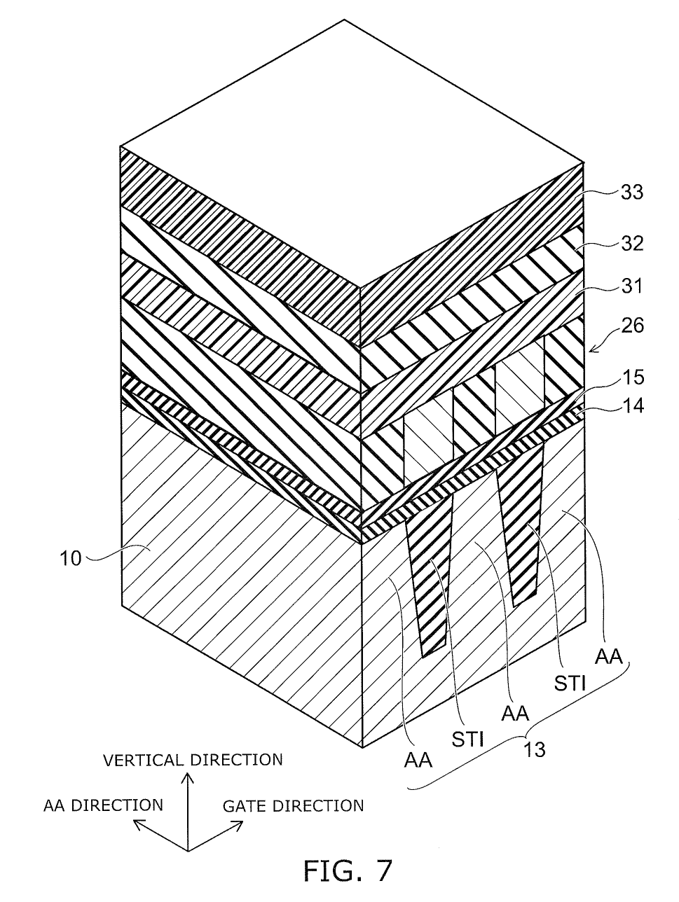

Next, as shown in FIG. 7, an organic film 31, a silicon oxide film 32, and a photoresist film 33 are formed in this order on the entire surface of the composite film 26.

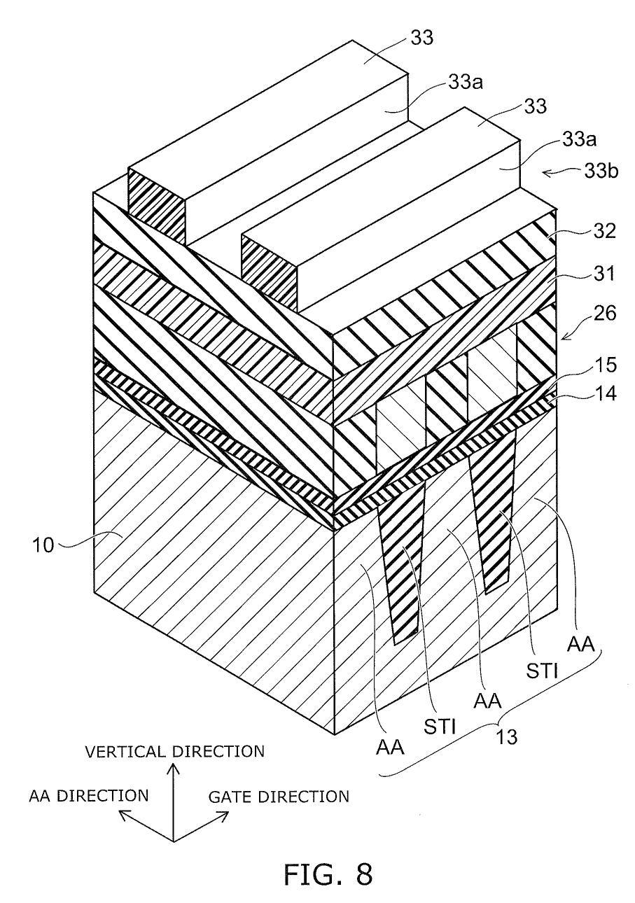

Next, as shown in FIG. 8, the photoresist film 33 is processed by lithography. Thus, a groove-shaped opening 33a extending in the gate direction is formed. The opening 33a is formed in the region where a recessed channel region is to be formed. Thus, the photoresist film 33 is patterned into a mask pattern 33b. Next, etching is performed using the mask pattern 33b as a mask to selectively remove the silicon oxide film 32 and the organic film 31.

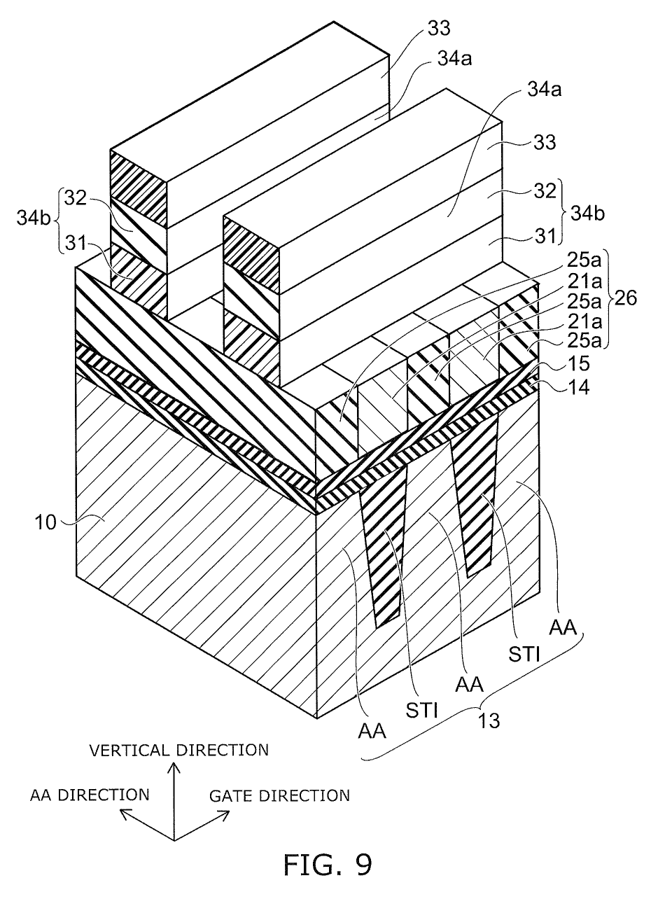

Thus, as shown in FIG. 9, a mask pattern 34b made of the organic film 31 and the silicon oxide film 32 and including openings 34a extending in the gate direction is formed. At this time, the silicon portions 21a and the oxide portions 25a alternately arranged are exposed at the bottom of the opening 34a.

Next, etching is performed on the composite film 26 using the mask pattern 34b as a mask and the stopper film 15 as an etching stopper. Specifically, etching is performed on the silicon portion 21a made of amorphous silicon under an optimal condition such that a sufficient etching selection ratio is ensured relative to the stopper film 15 made of silicon nitride. For instance, the gas used as an etching gas is a mixed gas of hydrogen bromide (HBr) and oxygen (O₂). At this time, sufficient overetching is performed so that the silicon portion 21a is not left immediately below the opening 34a.

Furthermore, etching is performed on the oxide portion 25a made of silicon oxide under an optimal condition such that a sufficient etching selection ratio is ensured relative to the stopper film 15 made of silicon nitride. For instance, the gas used as an etching gas is a mixed gas of octafluorocyclobutane (C₄F₈), oxygen (O₂), and argon (Ar). Alternatively, the gas used as an etching gas is a mixed gas of hexafluoro-1,3-butadiene (C₄F₆), oxygen (O₂), and argon (Ar). At this time, sufficient overetching is performed so that the oxide portion 25a is not left immediately below the opening 34a. Here, the order of the etching of the silicon portion 21a and the etching of the oxide portion 25a is arbitrary.

Thus, in the etching of the composite film 26, the stopper film 15 can be used as an etching stopper. Hence, the silicon portion 21a and the oxide portion 25a can be etched independently. Thus, each portion can be etched under an optimal condition. Furthermore, etching can be reliably stopped at the stopper film 15. Hence, the silicon portion 21a and the oxide portion 25a can be sufficiently overetched. Thus, the shape of each portion can be accurately controlled.

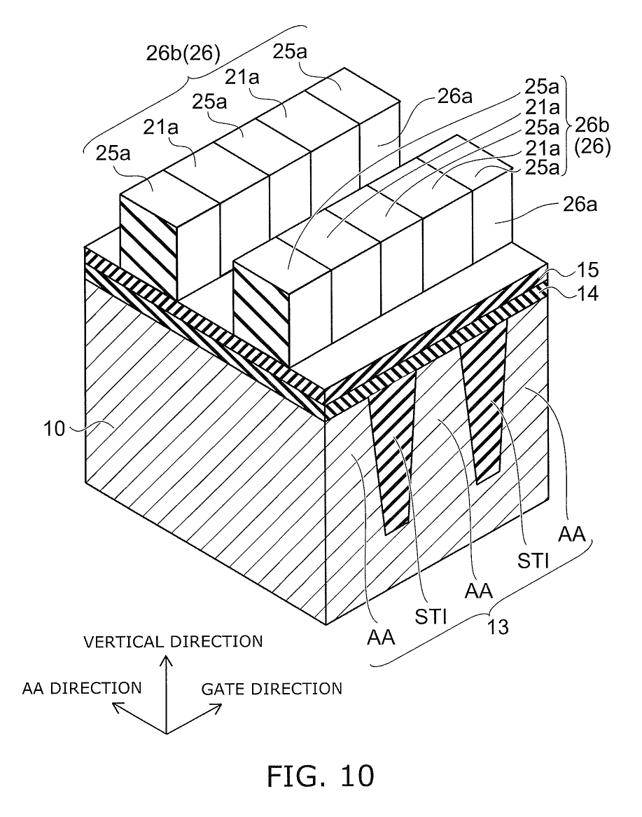

As a result, as shown in FIG. 10, a mask film 26b is formed on the base material 13. In the mask film 26b, openings 26a extending in the gate direction are formed in the composite film 26. The mask film 26b includes the oxide portion 25a located immediately above the active area AA and made of silicon oxide, and the silicon portion 21a located immediately above the shallow trench isolation STI and made of amorphous silicon. The opening 26a is formed in both the oxide portion 25a and the silicon portion 21a.

Next, etching is performed using the mask film 26b as a mask to remove the stopper film 15 and the sacrificial film 14. Next, anisotropic etching such as RIE (reactive ion etching) is performed on the active areas AA and the shallow trench isolations STI using the mask film 26b as a mask. This etching is performed under a condition favorable to control the cross-sectional shape of the active area AA. That is, etching is performed under a condition suitable for etching silicon. In such etching, the etching rate of silicon is higher than the etching rate of silicon oxide. Here, “silicon” encompasses “amorphous silicon”, “single crystal silicon”, and “polycrystalline silicon”. For instance, the gas used as an etching gas is a mixed gas of a fluorine-containing gas, such as methane tetrafluoride (CF₄) gas, added with a halogen-containing gas such as hydrogen bromide (HBr) or chlorine (Cl₂), or a gas having a sidewall protecting effect such as oxygen (O₂) or nitrogen (N₂).

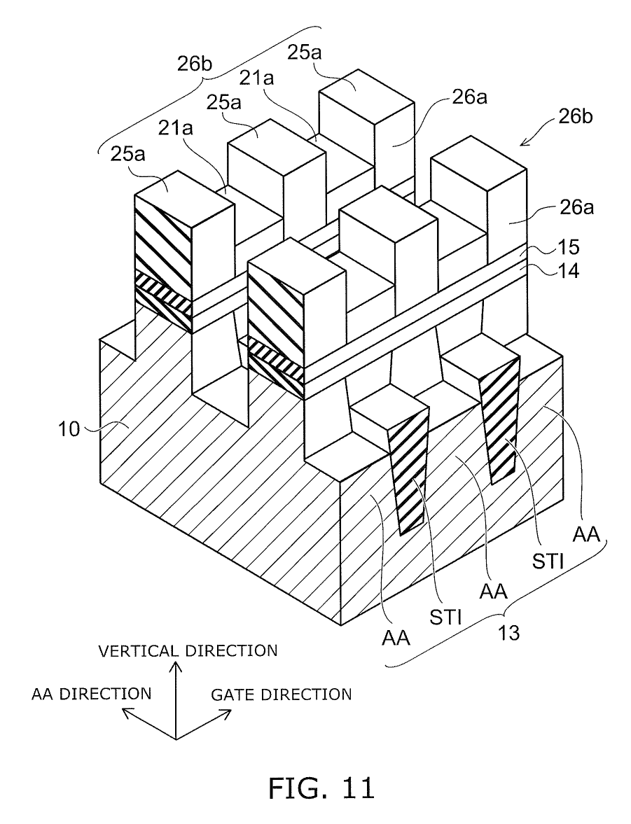

Thus, as shown in FIG. 11, at the etching start time, the etching rate of the active area AA made of single crystal silicon is higher than the etching rate of the shallow trench isolation STI made of silicon oxide. Immediately below the opening 26a of the mask film 26b, the upper surface of the active area AA is made lower than the upper surface of the shallow trench isolation STI. On the other hand, in the mask film 26b, the etching rate of the silicon portion 21a made of amorphous silicon is higher than the etching rate of the oxide portion 25a made of silicon oxide. Thus, the upper surface of the silicon portion 21a is made lower than the upper surface of the oxide portion 25a.

As a result, in the vertical direction, the distance between the upper surface of the oxide portion 25a and the upper surface of the active area AA is made longer than the distance between the upper surface of the silicon portion 21a and the upper surface of the shallow trench isolation STI. Thus, the vertical length of the space (hereinafter referred to as “mask space”) formed from the opening 26a of the mask film 26b and the etched portion of the base material 13 is made relatively long immediately above the active area AA, and made relatively short immediately above the shallow trench isolation STI. That is, the aspect ratio of the mask space immediately above the active area AA is made higher than the aspect ratio of the mask space immediately above the shallow trench isolation STI.

If the aspect ratio of the mask space is high, the number of ions and radicals reaching the bottom surface of the mask space, i.e., the etched surface, is decreased, and the etching rate is made lower. Thus, as the etching proceeds, the etching rate of the active area AA is made lower than that at the etching start time. On the other hand, the etching rate of the shallow trench isolation STI decreases less significantly than the etching rate of the active area AA. Thus, the base material 13 is etched under a condition such that the etching rate of silicon is higher than the etching rate of silicon oxide. This in itself serves to make the etching rate of the active area AA higher than the etching rate of the shallow trench isolation STI. However, the aforementioned influence of the aspect ratio of the mask space, i.e., the so-called microloading effect, serves to make the etching rate of the active area AA lower than the etching rate of the shallow trench isolation STI.

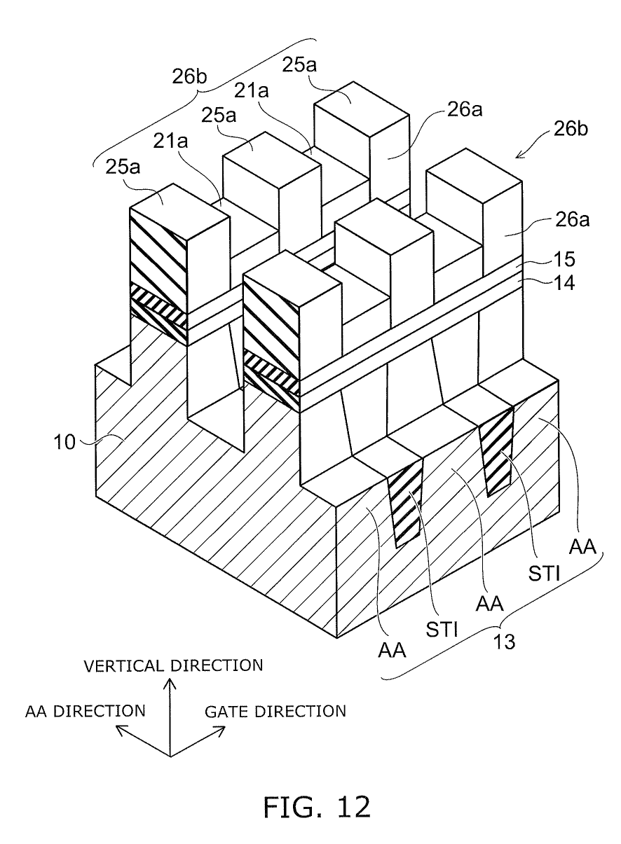

As a result, as shown in FIG. 12, at the etching end time, as compared with the etching start time, immediately below the opening 26a, the height of the upper surface of the active area AA and the height of the upper surface of the shallow trench isolation STI are made close to each other. More specifically, if the base material 13 is etched under a condition favorable to control the cross-sectional shape of the active area AA, the etching rate of silicon is inevitably made higher than the etching rate of silicon oxide. However, as in the embodiment, if the mask film 26b is a composite film, this difference in etching rate is reduced. Thus, the etching rate of the active area AA and the etching rate of the shallow trench isolation STI are made close to each other. As a result, the height of the etching surface of the active area AA and the height of the etching surface of the shallow trench isolation STI tend to be aligned. Thus, the shallow trench isolation STI can be reliably etched simultaneously with controlling the shape of the active area AA.

After completing the etching of the active area AA and the shallow trench isolation STI, the sacrificial film 14 is stripped. Thus, the remaining portion of the mask film 26b is removed in conjunction with the stopper film 15.

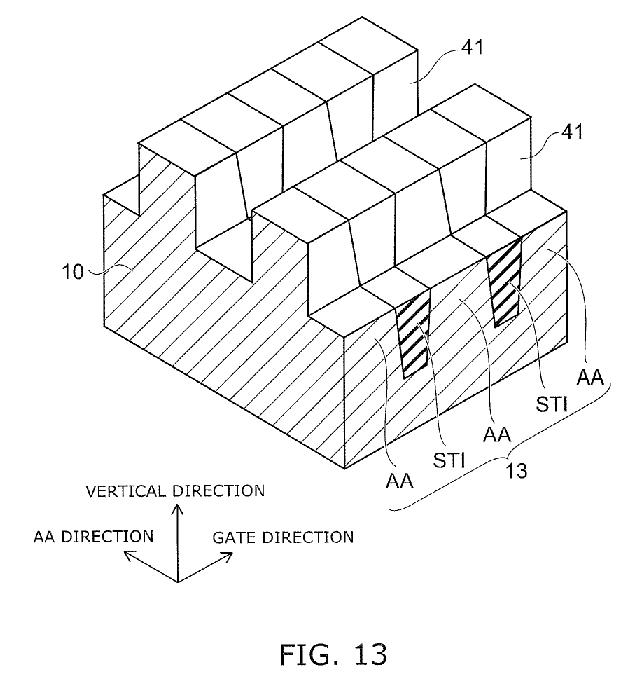

Thus, as shown in FIG. 13, a plurality of trenches 41 extending in the gate direction are formed in the base material 13.

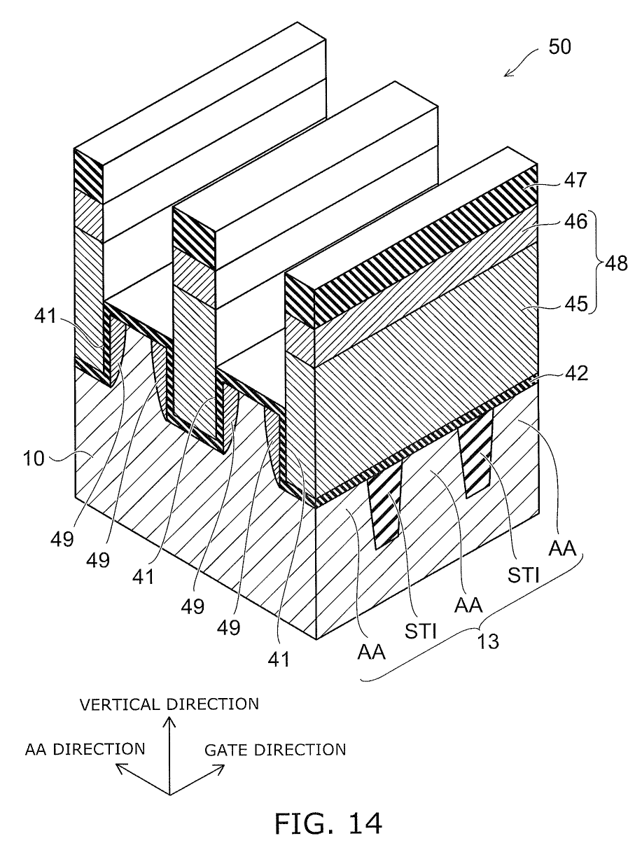

Next, as shown in FIG. 14, thermal oxidation treatment, for instance, is performed to form a gate insulating film 42 on the exposed surface of the active area AA. Next, polysilicon doped with impurity is deposited on the entire surface to form a polysilicon film 45. The polysilicon film 45 is buried in the trench 41, and located also on the base material 13. Next, on the polysilicon film 45, a tungsten nitride film (not shown) as a barrier metal, a tungsten film 46, a silicon nitride film 47, and a resist film (not shown) are formed in this order.

Next, the resist film is patterned by lithography and left only immediately above the trench 41. Next, by etching, the pattern of the resist film is transferred successively to the silicon nitride film 47, the tungsten film 46, and the polysilicon film 45. In this etching step, the resist film is eliminated. Thus, the polysilicon film 45 and the tungsten film 46 are left only inside and immediately above the trench 41 to form a gate electrode 48. The gate electrode 48 is formed like a stripe extending in the gate direction. Next, side walls (not shown) which consist of such as silicon nitride for example, are formed on the side surfaces of the gate electrode 48. Next, ion implantation of impurity such as phosphorus into the uppermost portion of the active area AA is performed with the gate electrode 48 and the side walls as a mask. Thus, a source/drain region 49 is formed on the side surface of the gate electrode 48 in the active area AA. Subsequently, by the conventional method, an upper interconnect structure (not shown) is formed. Thus, a semiconductor device 50 including recessed channel transistors is manufactured.

Next, the operation and effect of the embodiment are described.

In the etching of the active area AA and the shallow trench isolation STI shown in FIGS. 11 and 12, unlike the etching of the composite film 26 shown in FIG. 9, the stopper film cannot be used. Thus, it is impossible to sufficiently remove one of the active area AA and the shallow trench isolation STI by overetching, and then sufficiently remove the other by overetching. Hence, it is necessary to sufficiently etch the shallow trench isolation STI while preventing the overetching of the active area AA.

Thus, in the embodiment, as shown in FIG. 10, a mask film 26b including the silicon portion 21a and the oxide portion 25a is formed on the base material 13 including the active area AA and the shallow trench isolation STI. Then, etching is performed using the mask film 26b as a mask to process the active area AA and the shallow trench isolation STI. Thus, as shown in FIGS. 11 and 12, in the active area AA made of silicon originally having a high etching rate, etching is suppressed because the aspect ratio of the mask space is made higher. As a result, in the vertical direction, the position of the upper surface of the active area AA and the position of the upper surface of the shallow trench isolation STI are made close to each other. Hence, the trench 41 can be formed uniformly in the gate direction. Thus, a gate electrode 48 can be shaped uniformly. This can improve the characteristics of the recessed channel transistor.

In the following, the operation and effect of the embodiment are described in comparison with comparative examples.

In the comparative examples described below, in etching the active area AA and the shallow trench isolation STI, a mask film (not shown) having a uniform composition is used. That is, in this mask film, the composition of the portion located immediately above the active area AA and the composition of the portion located immediately above the shallow trench isolation STI are identical to each other. For instance, these portions are formed from amorphous silicon.

First, a first comparative example is described.

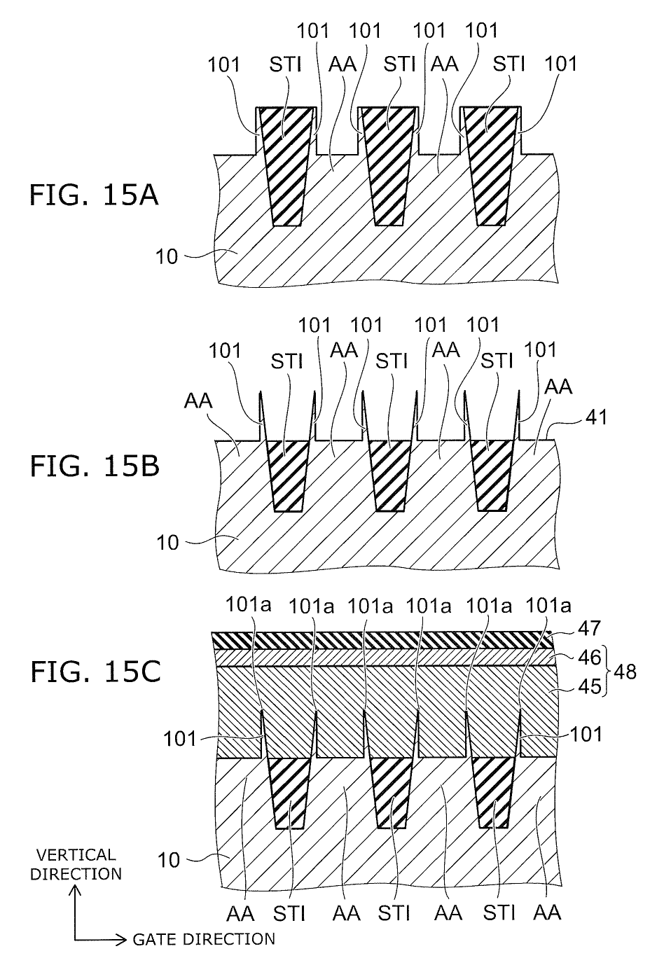

FIGS. 15A to 15C are process sectional views illustrating a method for manufacturing a semiconductor device according to this comparative example.

As shown in FIG. 15A, in this comparative example, the active area AA is previously etched under a condition suitable for etching silicon. However, at this time, the shallow trench isolation STI has an inverse taper shape. Hence, as viewed from above, the portion behind the shallow trench isolation STI is etched more slowly. This leaves fence-like protrusions 101. Here, if a stopper film were present below the active area AA, the protrusion 101 could be removed by sufficiently overetching the active area AA. However, in reality, no stopper film is present below the active area AA. Hence, it is difficult to remove the protrusion 101.

Next, as shown in FIG. 15B, the shallow trench isolation STI is etched under a condition suitable for etching silicon oxide. In this case, the shallow trench isolation STI made of silicon oxide is removed. However, the protrusion 101 made of silicon is scarcely removed, and left upright from the bottom surface of the trench 41.

Next, as shown in FIG. 15C, a gate electrode 48 is formed by depositing e.g. polysilicon. Here, the protrusion 101 is left in the state of digging into the gate electrode 48. As a result, after completion of the semiconductor device, when the recessed channel transistor is operated, the electric field concentrates on the tip portion 101a of the protrusion 101. Thus, the recessed channel transistor is made more susceptible to being turned on. This degrades the characteristics of the semiconductor device.

Next, a second comparative example is described.

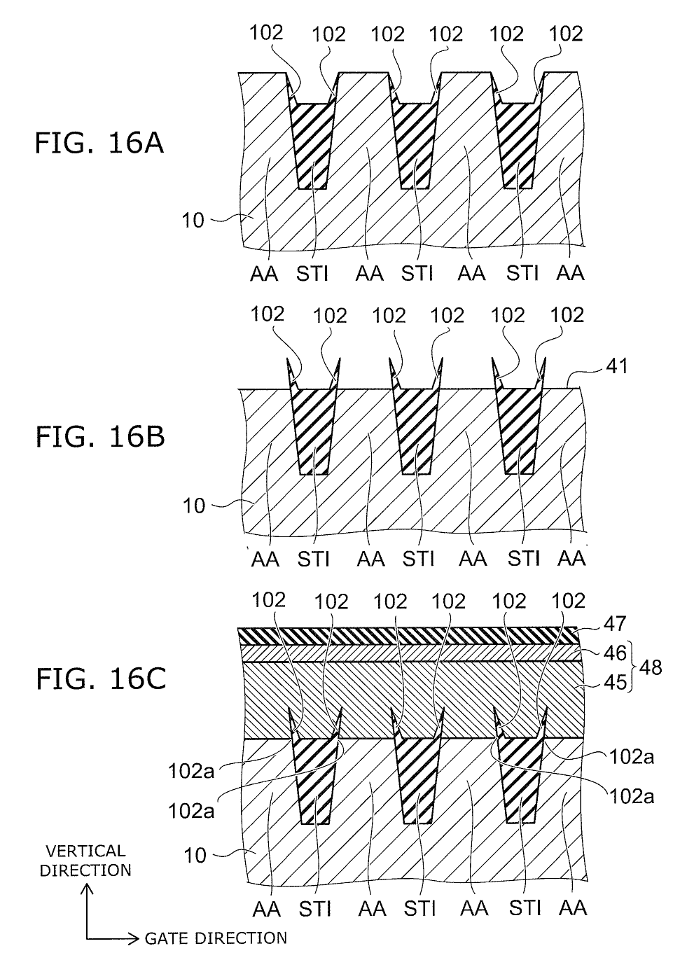

FIGS. 16A to 16C are process sectional views illustrating a method for manufacturing a semiconductor device according to this comparative example.

As shown in FIG. 16A, in this comparative example, the shallow trench isolation STI is previously etched under a condition suitable for etching silicon oxide. However, it is difficult to vertically etch silicon oxide. Hence, silicon oxide may be left on the side surface of the unprocessed active area AA to form fence-like protrusions 102. Also in this comparative example, no stopper film is present below the shallow trench isolation STI. Hence, it is difficult to remove the protrusion 102 by overetching.

Next, as shown in FIG. 16B, the active area AA is etched under a condition suitable for etching silicon. At this time, the protrusion 102 made of silicon oxide is not removed, but left upright from the bottom surface of the trench 41.

Then, as shown in FIG. 16C, when the gate electrode 48 is formed, the protrusion 102 digs into the gate electrode 48. As a result, the electric field concentrates on the root portion 102a of the protrusion 102. This degrades the characteristics of the semiconductor device.

Next, a third comparative example is described.

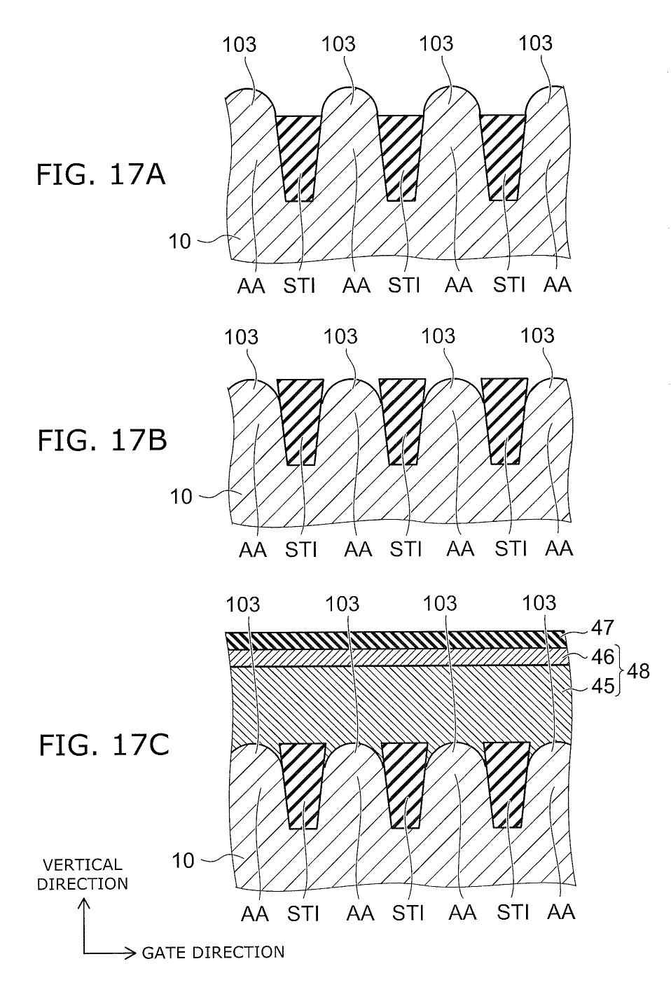

FIGS. 17A to 17C are process sectional views illustrating a method for manufacturing a semiconductor device according to this comparative example.

As shown in FIG. 17A, in this comparative example, the shallow trench isolation STI is previously etched as in the above second comparative example. However, the etching is performed with higher acceleration energy than in the second comparative example. This can prevent the formation of the protrusion 102 (see FIG. 16A). However, the corner portion of the active area AA is etched and causes shoulder loss. As a result, a protrusion 103 protruding upward is formed at the widthwise center of the active area AA.

Next, as shown in FIG. 17B, the active area AA is etched. Nevertheless, the protrusion 103 is left.

As shown in FIG. 17C, if a gate electrode 48 is formed in this state, the protrusion 103 is buried in the gate electrode 48. Thus, when voltage is applied to the gate electrode 48, the electric field concentrates on the protrusion 103. This degrades the characteristics of the semiconductor device.

Alternatively, in order to avoid the situation described in the above first to third comparative examples, etching can be performed under a condition such that the etching rate of silicon and the etching rate of silicon oxide are nearly equal. However, this significantly restricts the process condition such as the kind of etching gas and the ion acceleration voltage. On the other hand, in a recessed channel transistor, the cross-sectional shape of the gate electrode such as the dimension and the side surface taper angle greatly affects the characteristics of the transistor. Hence, the cross-sectional shape of the trench 41 also needs to be controlled accurately. This requires shape control of the trench 41 under an extremely restricted condition that the etching rate of silicon and the etching rate of silicon oxide are nearly equal. Hence, the process is made extremely difficult.

For instance, to achieve equality between the etching rate of silicon and the etching rate of silicon oxide, methane tetrafluoride (CF₄) gas can be used as an etching gas. However, it is difficult to accurately control the etching shape of the active area AA by solely using methane tetrafluoride gas. Thus, for instance, it is necessary to simultaneously use another halogen gas such as hydrogen bromide (HBr) or chlorine (Cl₂) typically used to etch silicon. However, upon mixing such a halogen gas with the etching gas, the etching rate of silicon oxide decreases and loses the balance with the etching rate of silicon

In contrast, according to the first embodiment, etching is performed using a mask film 26b with a composite structure. Thus, even if etching is performed under a condition suitable for etching the active area AA, the shallow trench isolation STI can also be etched entirely with a high etching rate because of the microloading effect. As a result, the active area AA and the shallow trench isolation STI can be simultaneously etched. Thus, a trench 41 with a uniform shape can be formed. As a result, a semiconductor device including recessed channel transistors with good characteristics can be manufactured.

In the first embodiment, in the mask film 26b provided on the base material 13, the oxide portion 25a made of silicon oxide is located immediately above the active area AA made of silicon, and the silicon portion 21a made of silicon is located immediately above the shallow trench isolation STI made of silicon oxide. However, the invention is not limited thereto, as long as the portion of the mask film having a relatively low etching rate is located immediately above the portion of the base material having a relatively high etching rate, and the portion of the mask film having a relatively high etching rate is located immediately above the portion of the base material having a relatively low etching rate.

For instance, the mask film may be a mask film including a silicon portion made of silicon and a nitride portion made of silicon nitride. In this case, under the etching condition suitable for etching silicon, the etching rate of the nitride portion is lower than that of the silicon portion. Hence, the nitride portion is located immediately above the portion of the base material having a relatively high etching rate, e.g., immediately above the active area AA.

Alternatively, the mask film may be a mask film including a silicon portion made of silicon and a metal portion made of a metal. The metal can be e.g. aluminum, titanium, or tantalum. In this case, under the etching condition suitable for etching silicon, the etching rate of the metal portion is lower than that of the silicon portion. Hence, the metal portion is located immediately above the portion of the base material having a relatively high etching rate.

Next, a second embodiment is described.

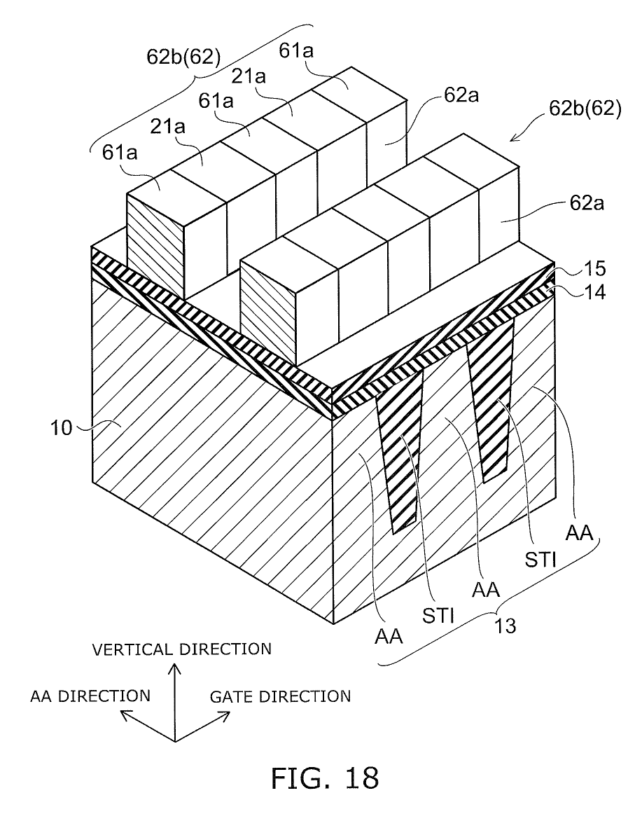

FIG. 18 is a perspective sectional view illustrating a method for manufacturing a semiconductor device according to the embodiment.

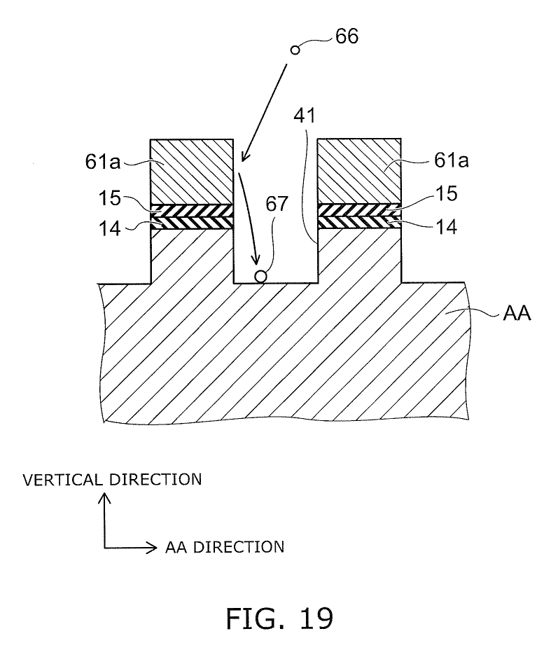

FIG. 19 is a sectional view illustrating the method for manufacturing a semiconductor device according to the embodiment.

In the embodiment, the mask film used to etch the base material 13 is a mask film including a silicon portion made of amorphous silicon and a carbon portion made of carbon. The carbon portion is located immediately above the active area AA.

First, as in the above first embodiment, the steps shown in FIGS. 1 to 4 are performed.

Next, in the step shown in FIG. 5, in the above first embodiment, a silicon oxide film 25 is formed. However, in the embodiment, instead of the silicon oxide film 25, a carbon film made of carbon is formed.

Then, as in the step shown in FIG. 6, planarization treatment such as CMP is performed to form a composite film 62. In the composite film 62, silicon portions 21a shaped like stripes extending in the AA direction and made of silicon, and carbon portions 61a (see FIG. 18) shaped like stripes extending in the AA direction and made of carbon, are alternately arranged along the gate direction.

Next, steps similar to those shown in FIGS. 7 to 9 are performed. Thus, a plurality of openings 62a shaped like stripes extending in the gate direction are formed in the composite film 62. Here, the etching gas used to etch the carbon portion is a mixed gas of hydrogen bromide (HBr) gas or chlorine (Cl₂) gas added with a fluorine-containing gas.

Thus, as shown in FIG. 18, a mask film 62b is formed on the base material 13. In the mask film 62b, openings 62a extending in the gate direction are formed in the composite film 62. The mask film 62b includes the carbon portion 61a located immediately above the active area AA and made of carbon, and the silicon portion 21a located immediately above the shallow trench isolation STI and made of amorphous silicon. The opening 62a is formed in both the carbon portion 61a and the silicon portion 21a.

Next, anisotropic etching such as RIE is performed on the active areas AA and the shallow trench isolations STI using the mask film 62b as a mask. As in the above first embodiment, this etching is performed under a condition favorable to control the cross-sectional shape of the active area AA. That is, etching is performed under a condition suitable for etching silicon.

Thus, at the etching start time, the etching rate of the active area AA made of single crystal silicon is higher than the etching rate of the shallow trench isolation STI made of silicon oxide. Immediately below the opening 62a of the mask film 62b, the upper surface of the active area AA is made lower than the upper surface of the shallow trench isolation STI.

However, as shown in FIG. 19, the carbon material 67 sputtered from the carbon portion 61a by ions 66 of the etching gas is deposited on the etching surface of the active area AA. Here, the deposited material may be a mixture or compound of carbon including the carbon material 67. This hampers the etching of the active area AA and decreases the etching rate. As a result, as in the above first embodiment, the etching rate of the active area AA is made close to the etching rate of the shallow trench isolation STI. Thus, at the bottom surface of the trench 41, the height of the portion constituted by the active area AA and the height of the portion constituted by the shallow trench isolation STI tend to be aligned. The manufacturing method, operation, and effect of the embodiment other than the foregoing are similar to those of the above first embodiment.

The embodiments described above can realize a method for manufacturing a semiconductor device capable of uniformly forming the trench.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A method for manufacturing a semiconductor device, comprising:
forming a mask film on a base material including a first portion made of silicon and a second portion made of silicon oxide, the mask film including a third portion located immediately above the first portion and made of silicon oxide and a fourth portion located immediately above the second portion and made of silicon, with an opening formed in both the third portion and the fourth portion; and
selectively removing the first portion and the second portion respectively by etching using the mask film as a mask under a condition such that etching rate of silicon is higher than etching rate of silicon oxide.

2. The method according to claim 1, wherein the etching is performed by using, as an etching gas, a mixed gas including a fluorine-containing gas and one or more gases selected from the group consisting of hydrogen bromide, nitrogen, oxygen, and chlorine.

3. The method according to claim 1, wherein
the first portion and the second portion are shaped like stripes extending in a direction parallel to an upper surface of the base material,
the first portion and the second portion are alternately arranged, and
the opening of the mask film extends in the arranging direction of the first portion and the second portion.

4. The method according to claim 1, wherein the forming a mask film includes:
forming a first material film made of silicon on the base material;
forming a first mask pattern on the first material film, the first mask pattern having an opening formed immediately above the first portion;
forming the fourth portion by etching using the first mask pattern as a mask to selectively remove the first material film;
forming a second material film made of silicon oxide so as to cover the fourth portion;
forming the third portion by removing an upper portion of the second material film to remove the second material film from immediately above the fourth portion and leave the second material film on a lateral side of the fourth portion;
forming a second mask pattern on the third portion and the fourth portion, the second mask pattern having an opening formed both immediately above the third portion and immediately above the fourth portion; and
selectively removing the third portion and the fourth portion respectively by etching using the second mask pattern as a mask.

5. A method for manufacturing a semiconductor device, comprising:
forming a mask film on a base material including a first portion made of a first material and a second portion made of a second material different from the first material, the mask film including a third portion located immediately above the first portion and made of a third material and a fourth portion located immediately above the second portion and made of a fourth material different from the third material, with an opening formed in both the third portion and the fourth portion; and
selectively removing the first portion and the second portion respectively by etching using the mask film as a mask under a condition such that etching rate of the fourth material is higher than etching rate of the third material and etching rate of the first material is higher than etching rate of the second material.

6. The method according to claim 5, wherein the fourth material is identical to the first material, and the third material is identical to the second material.

7. The method according to claim 6, wherein the first material and the fourth material are silicon, and the second material and the third material are silicon oxide.

8. The method according to claim 7, wherein the etching is performed by using, as an etching gas, a mixed gas including a fluorine-containing gas and one or more gases selected from the group consisting of hydrogen bromide, nitrogen, oxygen, and chlorine.

9. The method according to claim 5, wherein the first portion and the second portion are shaped like stripes extending in a direction parallel to an upper surface of the base material,
the first portion and the second portion are alternately arranged, and
the opening of the mask film extends in the arranging direction of the first portion and the second portion.

10. The method according to claim 5, wherein the forming a mask film includes:
forming a first material film made of the fourth material on the base material;
forming a first mask pattern on the first material film, the first mask pattern having an opening formed immediately above the first portion;
forming the fourth portion by etching using the first mask pattern as a mask to selectively remove the first material film;
forming a second material film made of the third material so as to cover the fourth portion;
forming the third portion by removing an upper portion of the second material film to remove the second material film from immediately above the fourth portion and leave the second material film on a lateral side of the fourth portion;
forming a second mask pattern on the third portion and the fourth portion, the second mask pattern having an opening formed both immediately above the third portion and immediately above the fourth portion; and
selectively removing the third portion and the fourth portion respectively by etching using the second mask pattern as a mask.

11. A method for manufacturing a semiconductor device, comprising:
forming a mask film on a base material including a first portion made of a first material and a second portion made of a second material different from the first material, the mask film including a third portion located immediately above the first portion and made of a third material and a fourth portion located immediately above the second portion and made of a fourth material different from the third material, with an opening formed in both the third portion and the fourth portion; and
selectively removing the first portion and the second portion respectively by etching using the mask film as a mask under a condition such that etching rate of the first material is higher than etching rate of the second material,
in the selectively removing, a material etched from the third portion being deposited on a surface of the first portion to suppress etching of the first portion.

12. The method according to claim 11, wherein the first material and the fourth material are silicon, the second material is silicon oxide, and the third material is carbon.

13. The method according to claim 12, wherein the etching is performed by using as an etching gas a mixed gas including a fluorine-containing gas and one or more gases selected from the group consisting of hydrogen bromide and chlorine.

14. The method according to claim 11, wherein
the first portion and the second portion are shaped like stripes extending in a direction parallel to an upper surface of the base material,
the first portion and the second portion are alternately arranged, and
the opening of the mask film extends in the arranging direction of the first portion and the second portion.

15. The method according to claim 11, wherein the forming a mask film includes:
forming a first material film made of the fourth material on the base material;
forming a first mask pattern on the first material film, the first mask pattern having an opening formed immediately above the first portion;
forming the fourth portion by etching using the first mask pattern as a mask to selectively remove the first material film;
forming a second material film made of the third material so as to cover the fourth portion;
forming the third portion by removing an upper portion of the second material film to remove the second material film from immediately above the fourth portion and leave the second material film on a lateral side of the fourth portion;
forming a second mask pattern on the third portion and the fourth portion, the second mask pattern having an opening formed both immediately above the third portion and immediately above the fourth portion; and
selectively removing the third portion and the fourth portion respectively by etching using the second mask pattern as a mask.
